(19) United States
(12) Patent Application Publication
(10) Pub. No.: US 2025/0300611 A1
(43) Pub. Date: Sep. 25, 2025

(54) PEAK CURRENT MEASUREMENT OF CLASS-D AMPLIFIER DRIVER UTILIZING CHARGE ACCUMULATION

(71) Applicant: Nuvoton Technology Corporation, Hsinchu (TW)

(72) Inventor: Chang-Xian Wu, San Jose, CA (US)

(21) Appl. No.: 18/610,241

(22) Filed: Mar. 19, 2024

(51) Int. Cl. H03F 3/217

(52) U.S. Cl. CPC H03F 3/2171; H03F 2200/03; H03F 2200/435; H03F 2200/462

(57) ABSTRACT

The class-D amplifier includes an output driver stage configured to output an output signal at an output node. The class-D amplifier also includes a current sensing circuit coupled to the output node of the output driver stage, and the current sensing circuit may include: a peak detector coupled to the output node of the output driver stage configured to capture a peak value of the output signal, and a current sensor coupled to the peak detector and configured to receive the peak value of the output signal and generate a sense current based on the peak value of the output signal.

### FIELD

This invention relates to the field of electronic circuits in audio systems. More particularly, the present invention relates to peak current measurement of a class-D amplifier driver.

### BACKGROUND

A class-D amplifier, also known as a switching amplifier, is an electronic amplifier in which transistors operate as binary switches. They are either fully on or fully off. Class-D amplifiers employ rail-to-rail output switching, where, ideally, their output transistors virtually always carry either zero current or zero voltage. Thus, their power dissipation is minimal, and they provide high efficiency over a wide range of power levels. Their advantageous high efficiency has propelled their use in various audio applications, from cell phones to flat screen televisions and home theater receivers. Class-D audio power amplifiers are more efficient than class-AB audio power amplifiers. Because of their greater efficiency, class-D amplifiers require smaller power supplies and eliminate heat sinks, thus significantly reducing overall system costs, size, and weight.

### BRIEF SUMMARY OF THE INVENTION

One general aspect includes a class-D amplifier. The class-D amplifier also includes an output driver stage configured to output an output signal at an output node. The class-D amplifier also includes a current sensing circuit coupled to the output node of the output driver stage, and the current sensing circuit may include: a peak detector coupled to the output node of the output driver stage configured to capture a peak value of the output signal, and a current sensor coupled to the peak detector and configured to receive the peak value of the output signal and generate a sense current based on the peak value of the output signal.

Implementations may include one or more of the following features. In some embodiments, the peak detector locks in the peak value of the output signal. In some embodiments, the peak detector may include an output node of the peak detector, and when the output signal at the output node of the output driver stage increases, a voltage level at the output node of the peak detector increases; when the output signal at the output node of the output driver stage decreases, the voltage level at the output node of the peak detector remains unchanged. In some embodiments, the peak detector may include: a first operational amplifier; a first n-type transistor; and a first capacitor. In some embodiments, a positive input terminal of the first operational amplifier is coupled to output node of the output driver stage, a negative input terminal of the first operational amplifier is coupled to an output node of the peak detector, and an output terminal of the first operational amplifier is coupled to a gate of the first n-type transistor. In some embodiments, a drain of the first n-type transistor is coupled to a higher power rail, and a source of the first n-type transistor is coupled to an output node of the peak detector. In some embodiments, the first capacitor is coupled between the output node of the peak detector and a lower power rail lower than the higher power rail.

In some embodiments, the, the peak detector further may include: a second n-type transistor; a third n-type transistor; and a second capacitor. In some embodiments, a drain of the second n-type transistor is coupled to the output node of the peak detector, a source of the second n-type transistor is coupled a second node, and the second capacitor is coupled between the second node and the lower power rail, and a drain of the third n-type transistor is coupled to the second node, and a source of the third n-type transistor is coupled to the lower power rail. In some embodiments, a gate of the second n-type transistor is coupled to a first clock signal, and a gate of the third n-type transistor is coupled to a second clock signal, and the second clock signal is complementary to the first clock signal. In some embodiments, a capacitance of the second capacitor is smaller than a capacitance of the first capacitor.

In some embodiments, the current sensor may include: a second operational amplifier; a sense transistor; a first p-type transistor; and a current mirror. In some embodiments, a negative input terminal of the second operational amplifier is coupled to the peak detector to receive the peak value of the output signal of the output driver stage, a positive input terminal of the second operational amplifier is coupled to a third node, and an output terminal of the second operational amplifier is coupled to a gate of the first p-type transistor, and a source of the first p-type transistor is coupled to the current mirror, and a drain of the first p-type transistor is coupled to the third node. In some embodiments, a drain of the sense transistor is coupled to the third node, and a source of the sense transistor is coupled to a lower power rail. In some embodiments, the current mirror may include: a second p-type transistor, where the source of the first p-type transistor is coupled to a drain and a gate of the second p-type transistor, and a source of the second p-type transistor is coupled to a higher power rail higher than the lower power rail; and a third p-type transistor, where a source of the third p-type transistor is coupled to the higher power rail, a gate of the third p-type transistor is coupled to the gate of the second p-type transistor, and a drain of the third p-type transistor is coupled to an output terminal of the current sensor. In some embodiments, the output terminal of the current sensor is coupled to a conversion circuit, and the conversion circuit may include: a capacitor coupled between the output terminal of the current sensor and the lower power rail; a comparator may include a negative input terminal coupled to the output terminal of the current sensor and a positive input terminal configured to receive a reference voltage; and a counter coupled to an output terminal of the comparator.

Another general aspect includes a method for operating a class-D amplifier. The method includes outputting an output signal at an output node of an output driver stage. The method also includes capturing, by a peak detector, a peak value of the output signal. The method also includes generating, by a current sensor, a sense current based on the peak value of the output signal.

Implementations may include one or more of the following features. Capturing the peak value of the output signal further may further include: locking in the peak value of the output signal. When the output signal increases, a voltage level at the output node of the peak detector increases, and when the output signal decreases, the voltage level at the output node of the peak detector remains unchanged. The method may include: converting the sense current to a digital sense current using a comparator and a counter.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a simplified schematic diagram illustrating a class-D amplifier, which is a conventional class-D amplifier with a feedback loop.

FIG. 1B is a waveform diagram illustrating the modulation of signals in the class-D amplifier 100 of FIG. 1A.

FIG. 2A is a diagram illustrating a conventional configuration of current sensing of a class-D amplifier.

FIG. 2B is a diagram illustrating the waveform of the voltage drop across the first sense resistor.

FIG. 2C is a diagram illustrating the output signal of a low pass filter amplifier corresponding to the voltage drop across the first sense resistor.

FIG. 2D is a diagram illustrating another conventional configuration of current sensing of a class-D amplifier.

FIG. 3A is a block diagram illustrating a current sensing circuit for a class-D amplifier in accordance with some embodiments.

FIG. 3B is a diagram illustrating an example of a sensing circuit for a class-D amplifier in accordance with some embodiments.

FIG. 4A is a diagram illustrating an example conversion circuit in accordance with some embodiments.

FIG. 4B is a diagram illustrating another example conversion circuit in accordance with some embodiments.

FIG. 5 is a flowchart diagram illustrating an example method for operating a class-D amplifier in accordance with some embodiments.

### DETAILED DESCRIPTION OF THE DISCLOSURE

The following disclosure provides many different embodiments, or examples, for implementing different features of the subject matter provided. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, source/drain (“S/D”) region(s) may refer to a source or a drain, individually or collectively dependent upon the context. For example, a device may include a first source/drain region and a second source/drain region, among other components. The first source/drain region may be a source region, whereas the second source/drain region may be a drain region, or vice versa. One of ordinary skill in the art would recognize many variations, modifications, and alternatives.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

Class D audio power amplifiers convert audio input signal into high-frequency pulses that switch the output transistors in accordance with the audio input signal. Some class-D amplifiers use pulse width modulators (PWM) to generate a series of conditioning pulses that vary in width according to the amplitude of the audio input signal. The width-varying pulses switch the output transistors at a fixed frequency. Other class-D amplifiers may rely upon other types of pulse modulators. The following discussion will mainly refer to pulse width modulators, but a person of ordinary skill in the art will recognize that class-D amplifiers may be configured with other types of modulators.

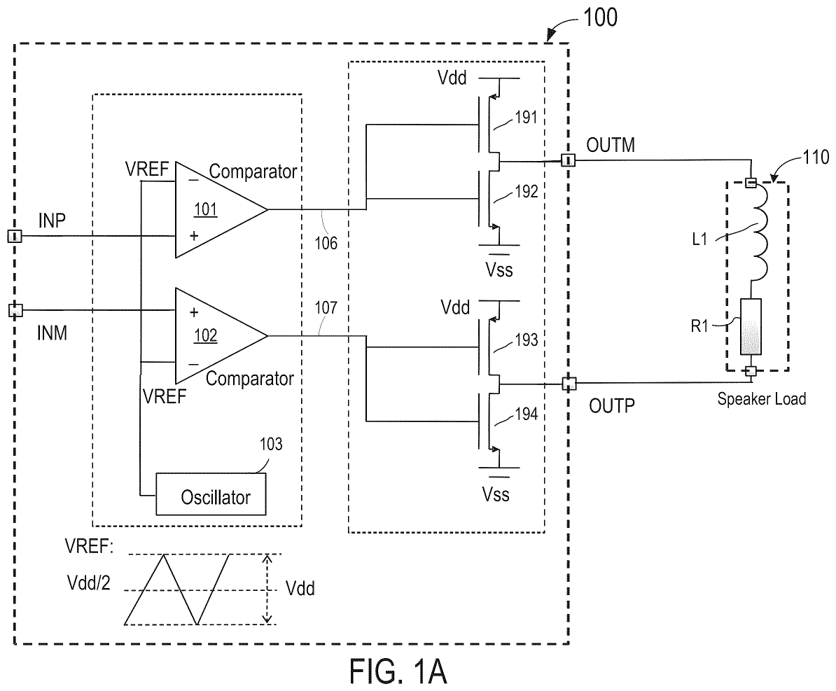

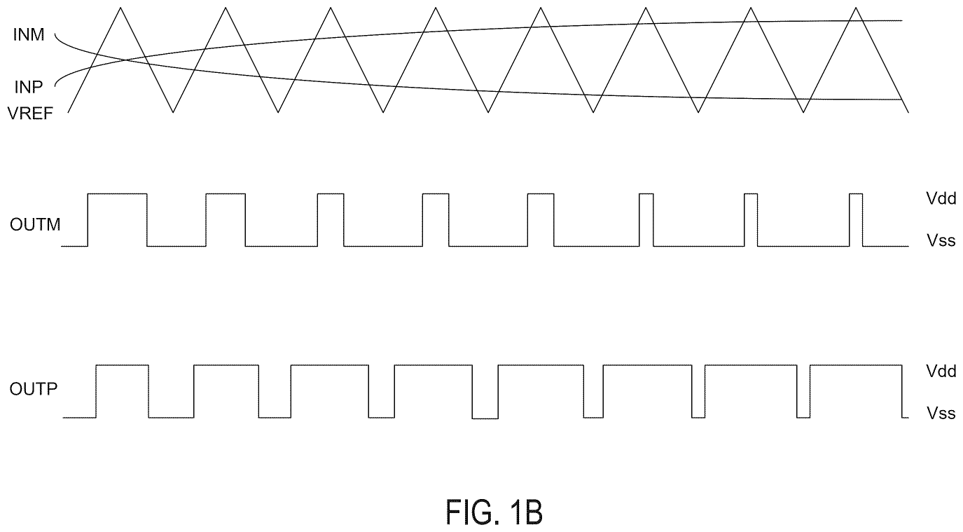

FIG. 1A is a simplified schematic diagram illustrating a class-D amplifier 100, which is a conventional class-D amplifier. As shown in FIG. 1A, the class-D amplifier 100 is a differential amplifier. A pair of differential audio input signals INP and INM (i.e., a first audio input signal INP and a second audio input signal INM) are input to a first comparator 101 and a second comparator 102, respectively. Each of the pair of differential audio input signals INP and INM is compared with a triangular signal (i.e., a signal having a triangular waveform) VREF generated from an oscillator 103 to generate a first PWM signal 106 and a second PWM signal 107, respectively. Since the first audio input signal INP and the second audio input signal INM are differential signals and the same triangular signal VREF is used as the reference signal, the first PWM signal and the second PWM signal 107 are differential signals as well. For example, if the first PWM signal has a duty cycle of 60%, the second PWM signal has a duty cycle of 40%; if the first PWM signal has a duty cycle of 70%, the second PWM signal has a duty cycle of 30%.

The first PWM signal 106 is coupled to the gates of output transistors 191 and 192, which are electrically connected together. The first PWM signal 106, therefore, controls the turning on and turning off the output transistors 191 and 192. The second PWM signal 107 is coupled to the gates of output transistors 193 and 194, which are electrically connected together. The second PWM signal 107, therefore, controls the turning on and turning off the output transistors 193 and 194. As a result, the first output signal OUTM and the second output signal OUTP of the class-D amplifier 100 are differential output signals as well. As shown in FIG. 1A, the first output signal OUTM and the second output signal OUTP are applied to two ends of a (speaker) load 110, which is represented by an inductor L1 and a resistor R1 in FIG. 1A.

FIG. 1B is a waveform diagram illustrating the modulation of signals in the class-D amplifier 100 of FIG. 1A. As shown in FIG. 1B, the first audio input signal INP and the second audio input signal INM are compared with the triangular signal VREF, as described above in connection with FIG. 1A. The output signals of the first comparator 101 and the second comparator 102 are pulse signals at a fixed frequency (i.e., a fixed cycle) whose pulse width is proportional to its corresponding audio input signal. As a result, the first output signal OUTM and the second output signal OUTP are two PWM signals, as shown in FIG. 1B.

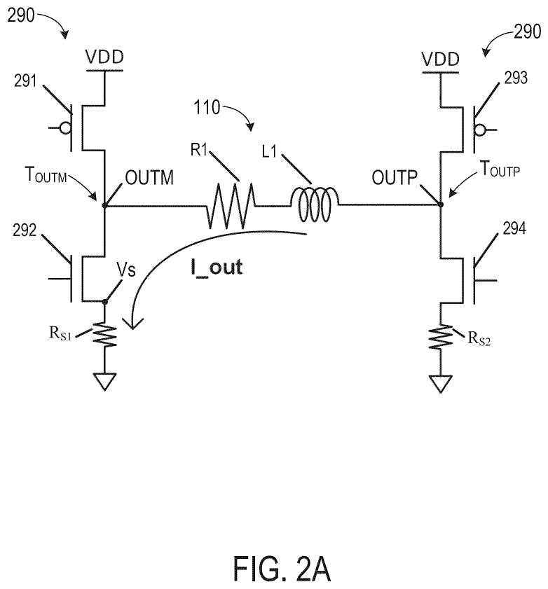

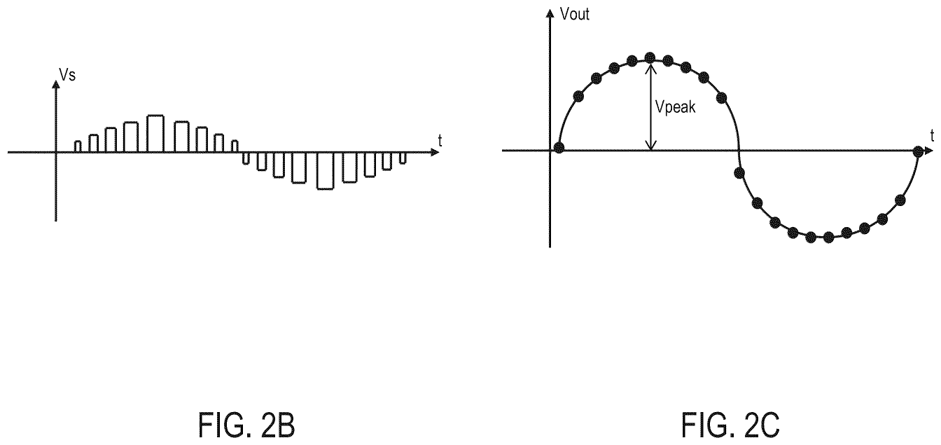

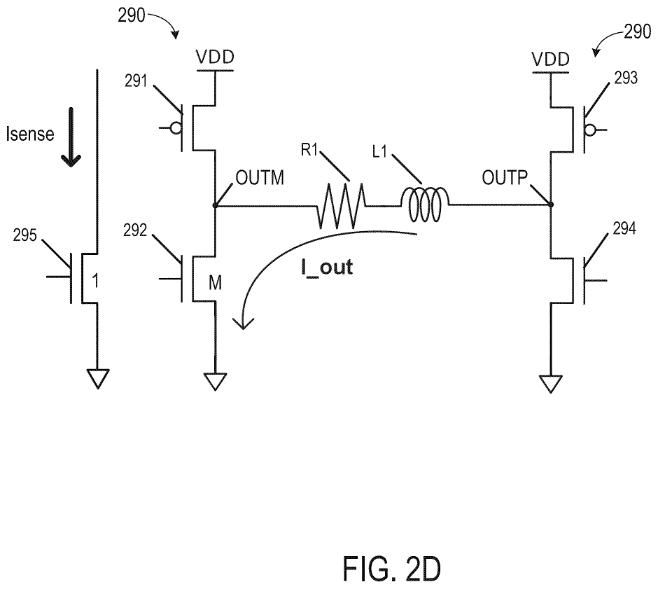

FIG. 2A is a diagram illustrating a conventional configuration of current sensing of a class-D amplifier. Similar to the example shown in FIG. 1A, an output driver stage 290 includes p-type output transistors 291 and 293 and n-type output transistors 292 and 294, connected in the manner shown in FIG. 2A. Specifically, the source of the p-type output transistor 291 is connected to a higher power rail (e.g., V_{DD}), the drain of the p-type output transistor 291 is connected to the drain of the n-type output transistor 292 at the first output terminal T_{OUTM}, and the source of the n-type output transistor 292 is connected to a lower power rail (e.g., V_{SS} or ground). The source of the p-type output transistor 293 is connected to a higher power rail (e.g., V_{DD}), the drain of the p-type output transistor 293 is connected to the drain of n-type output transistor 294 at the second output terminal T_{OUTP}, and the source of the p-type output transistor 293 is connected to a lower power rail (e.g., V_{SS} or ground). The speaker load 110, which includes the inductor L1 and the resistor R1, is connected between the first output terminal T_{OUTM} and the second output terminal T_{OUTP}.

A first sense resistor R_{S1} is connected between the lower power rail (e.g., V_{SS} or ground) and the source of the n-type output transistor 292. A second sense resistor R_{S2} is connected between lower power rail (e.g., V_{SS} or ground) and the source of the n-type output transistor 294. The first sense resistor R_{S1} and the second sense resistor R_{S2} act as current sensors that covert the voltage drops (Vs) across them into current values. The output current (I_out) can be calculated in accordance with I_out=V_{S}/R_{S1}.

FIG. 2B is a diagram illustrating the waveform of the voltage drop (Vs) across the first sense resistor R_{S1}. FIG. 2C is a diagram illustrating the output signal of a low pass filter amplifier corresponding to the voltage drop (Vs) across the first sense resistor R_{S1}. As shown in FIG. 2B, the waveform of the voltage drop (Vs) across the first sense resistor R_{S1} is like the PWM signal shown in FIG. 1B except that the envelope of the waveform is a sine wave. The voltage drop (Vs) is input to a low pass filter amplifier. The low pass filter amplifier typically has a relatively large gain and a resistor-capacitor (RC) circuit that consumes a significant chip area. The low pass filter amplifier can filter out high-frequency components of the signal, thereby making the signal smooth, and provide some gain. The output signal of the low pass filter amplifier is fed to an analog-to-digital converter (ADC), which converts the analog signal to a digital signal by sampling the analog signal. As shown in FIG. 2C, the post-sampling output signal (Vout) corresponds to the waveform of the voltage drop (Vs) across the first sense resistor R_{S1}. The peak (Vpeak) of the post-sampling output signal (Vout) is illustrated in FIG. 2C. Thus, the peak current (Ipeak) can be calculated in accordance with Ipeak=Vpeak/(g*R_{S}), whereas g is the gain of the low pass filter amplifier, and R_{S} is the resistance of the first sense resistor R_{S1}.

However, there are some drawbacks of this conventional configuration. The RC circuit and the ADC consume a significant chip area. Getting rid of the RC circuit and the ADC would significantly reduce the chip area used for current sensing, thereby saving cost.

FIG. 2D is a diagram illustrating another conventional configuration of current sensing of a class-D amplifier. Similar to the example shown in FIG. 1A, an output driver stage 290 includes p-type output transistors 291 and 293 and n-type output transistors 292 and 294, connected in the manner shown in FIG. 2A. Specifically, the source of the p-type output transistor 291 is connected to a higher power rail (e.g., V_{DD}), the drain of the p-type output transistor 291 is connected to the drain of the n-type output transistor 292 at the first output terminal T_{OUTM}, and the source of the n-type output transistor 292 is connected to a lower power rail (e.g., V_{SS} or ground). The source of the p-type output transistor 293 is connected to a higher power rail (e.g., V_{DD}), the drain of the p-type output transistor 293 is connected to the drain of n-type output transistor 294 at the second output terminal T_{OUTP}, and the source of the p-type output transistor 293 is connected to a lower power rail (e.g., V_{SS} or ground). The speaker load 110, which includes the inductor L1 and the resistor R1, is connected between the first output terminal T_{OUTM} and the second output terminal T_{OUTP}.

Unlike the configuration shown in FIG. 2A, where a first sense resistor R_{S1} is used for current sensing, a sense transistor 295 is instead used for current sensing in the configuration shown in FIG. 2D. The sense transistor 295 is connected in another branch parallel to the branch comprised of the p-type output transistor 291 and the n-type output transistor 292. The gate of the sense transistor 295 is connected to the gate of the n-type output transistor 292. The source of the sense transistor 295 is connected to the lower power rail (e.g., V_{SS} or ground). Thus, the source of the sense transistor 295 and the source of the n-type output transistor 292 are connected to the same voltage level. As a result, the gate-to-source voltage (V_{GS}) of the sense transistor 295 is equal to that of the n-type output transistor 292.

The drain current through a transistor, when the transistor is operating in the linear region, is calculated in accordance with the following equation:

$${I}_{D} = {μ}_{n} {C}_{ox} \frac{W}{L} ( ( {V}_{GS} - {V}_{th} ) {V}_{DS} - \frac{{V}_{DS}^{2}}{2} ) ,$$

whereas I_{D} is the drain current, μₙ is the charge-carrier effective mobility, C_{OX} is the gate oxide capacitance per unit area, W is the gate width, L is the gate length, V_{DS} is the voltage drop across the drain and the source, and Vₜₕ is the threshold voltage. As suggested by the equation above, if the sense transistor 295 and the n-type output transistor 292 are fabricated at the identical process corner, some of these parameters (μₙ, C_{OX}, Vₜₕ) are identical. As stated above, the gate-to-source voltage (V_{GS}) of the sense transistor 295 is equal to that of the n-type output transistor 292. Therefore, if the voltage drop across the drain and the source (V_{DS}) is identical, the drain current of the sense transistor 295 is proportional to that of the n-type output transistor 292, depending on the respective W/L ratio. In other words, the current ratio between these two transistors can be controlled by controlling the W/L ratio of the n-type output transistor 292 and the W/L ratio of the sense transistor 295. In the example shown in FIG. 2D, The W/L ratio of the n-type output transistor 292 is M times of the W/L ratio of the sense transistor 295. As a result, the drain current of the sense transistor 295 is 1/M of the drain current of the n-type output transistor 292, assuming that the voltage drop across the drain and the source (V_{DS}) is identical. It should be understood that M could be chosen from a variety of available values (e.g., 10, 100, 1000, 10000, etc.) depending on the circumstances.

However, the assumption that the voltage drop across the drain and the source (V_{DS}) is identical does not always hold. As a result, the sensed current (i.e., the drain current of the sense transistor 295) is not precisely 1/M of the drain current of the n-type output transistor 292, thereby introducing errors in the current sensing process.

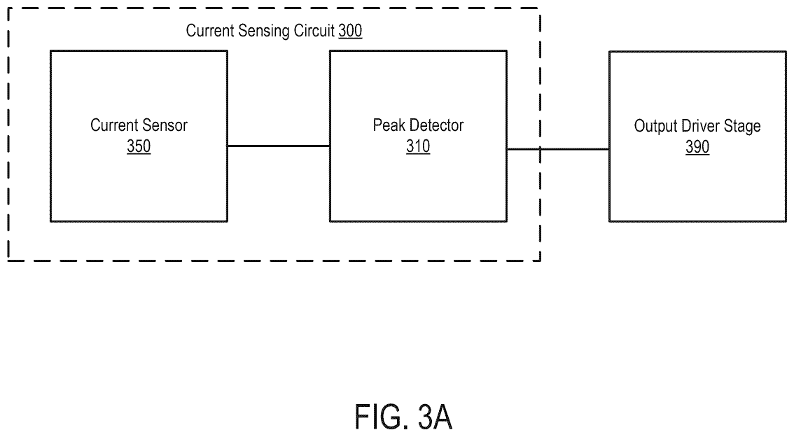

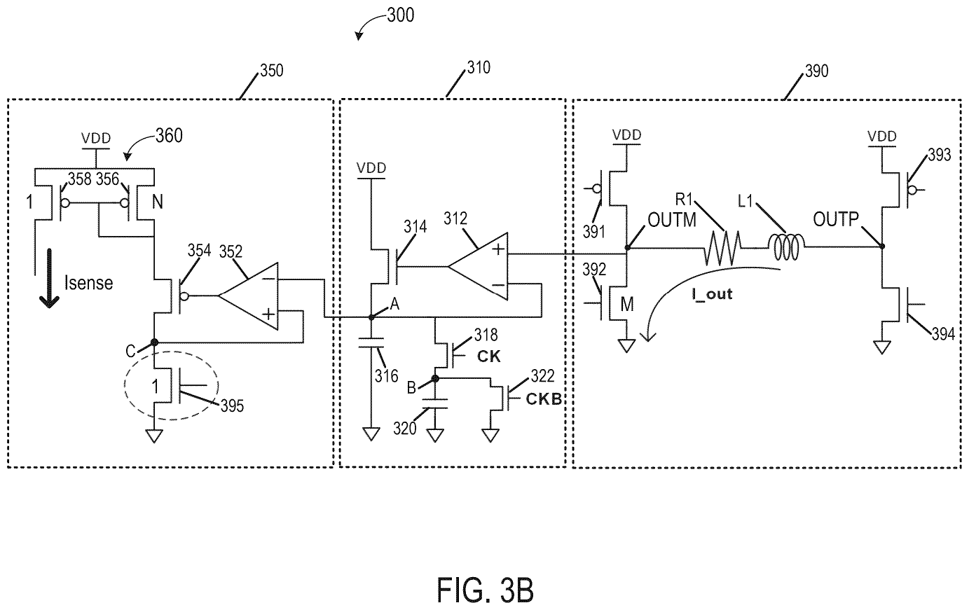

To address these deficiencies discussed in relation to FIGS. 2A-2D, a novel current sensing configuration and circuit is provided. FIG. 3A is a block diagram illustrating a current sensing circuit for a class-D amplifier in accordance with some embodiments. FIG. 3B is a diagram illustrating an example of a sensing circuit for a class-D amplifier in accordance with some embodiments.

As shown in FIG. 3A, the current sensing circuit 300 is coupled to the output driver stage 390 (like the output driver stage 290 shown in FIG. 2A) of a class-D amplifier (like the class-D amplifier 100 shown in FIG. 1A). The current sensing circuit 300 includes, among other components, a peak detector 310 and a current sensor 350. The peak detector 310 is coupled to the output driver stage 390 and configured to capture and lock in the peak value of the first output signal OUTM (like the V_{S} shown in FIG. 2A). One implementation of the peak detector 310 is shown in FIG. 3B. However, it should be understood that this example shown in FIG. 3B is exemplary rather than limiting, and other implementations may be employed. The current sensor 350 is coupled to the peak detector 310. The current sensor 350 is configured to receive the peak value of the output voltage captured by the peak detector 310 and generate a sense current based on the peak value of the output voltage. One implementation of the current sensor 350 is shown in FIG. 3B. However, it should be understood that this example shown in FIG. 3B is exemplary rather than limiting, and other implementations may be employed.

In the example shown in FIG. 3B, the peak detector 310 includes, among other components, an operational amplifier (may also be referred to as the “first operational amplifier”) 312, a first n-type transistor 314, a second n-type transistor 318, a third n-type transistor 322, a first capacitor 316, and a second capacitor 320. The positive input terminal of the operational amplifier 312, served as the input node of the peak detector 310, is coupled to the first output terminal T_{OUTM}, and the negative input terminal of the operational amplifier 312 is coupled to an output node A of the peak detector 310. The drain of the first n-type transistor 314 is coupled to the higher power rail (e.g., V_{DD}), the source of the first n-type transistor 314 is coupled to the output node A, and the gate of the first n-type transistor 314 is coupled to the output terminal of the operational amplifier 312.

The first capacitor 316 is coupled between the output node A and the lower power rail (e.g., V_{SS} or ground). The drain of the second n-type transistor 318 is coupled to the output node A, the source of the second n-type transistor 318 is coupled to a node B, and the gate of the second n-type transistor 318 is coupled to a clock signal (labeled as “CK” in FIG. 3B). The second capacitor 320 is coupled between the node B and the lower power rail (e.g., V_{SS} or ground). The drain of the third n-type transistor 322 is coupled to the node B, the source of the third n-type transistor 322 is coupled to the lower power rail (e.g., V_{SS} or ground), and the gate of the third n-type transistor 322 is coupled to a complementary clock signal (labeled as “CKB” in FIG. 3B) with respect to the clock signal (labeled as “CK” in FIG. 3B).

When the first output signal OUTM increases, the voltage level at the first input terminal of the operational amplifier 312 increases. As a result, the voltage level at the output terminal of the operational amplifier 312 increases accordingly. Since the output terminal of the operational amplifier 312 is coupled to the gate of the first n-type transistor 314, the first n-type transistor 314 is turned on. The voltage level at the output node A is accordingly pulled up to the higher power rail (e.g., V_{DD}) (minus the voltage drop across the source and the drain of the first n-type transistor 314).

When the first output signal OUTM decreases, the voltage level at the first input terminal of the operational amplifier 312 decreases. As a result, the voltage level at the output terminal of the operational amplifier 312 decreases accordingly. Since the output terminal of the operational amplifier 312 is coupled to the gate of the first n-type transistor 314, the first n-type transistor 314 is turned off. However, because of the existence of the first capacitor 316, there is no pull-down path for the voltage level at the output node A to decrease. In other words, the voltage level at the output node A can only change in one direction (i.e., increasing but not decreasing). The voltage level at the output node A remains unchanged when the first output signal decreases. As a result, the peak value of the first output signal OUTM at the first output terminal T_{OUTM} is captured and locked in at the output node A of the peak detector 310.

However, the peak voltage of OUTM exhibits variability, with distinct peak values corresponding to different sine waves. In order to effectively capture subsequent peak values, it is imperative to implement a compact discharge path, traditionally achieved through the utilization of a large resistor. However, the drawbacks associated with the use of large resistors, namely increased spatial requirements and elevated costs, prompt the exploration of alternative solutions. The present invention introduces a novel approach by employing a switched capacitor (the second capacitor 320 in FIG. 3B to be discussed below) as a more space-efficient and cost-effective substitute for the conventional resistor, thereby facilitating optimal discharge and enhanced peak value capture.

The second capacitor 320, the second n-type transistor 318, and the third n-type transistor 322 are introduced. The capacitance of the second capacitor 320 is smaller than the capacitance of the first capacitor 316. In one example, the capacitance of the second capacitor 320 is 0.1%, 1%, 5%, or 10% of the capacitance of the first capacitor 316. When the clock signal (labeled as “CK” in FIG. 3B) is at logical high, the second n-type transistor 318 is turned on. In the meantime, the complementary clock signal (labeled as “CKB” in FIG. 3B) is accordingly at logical low, the third n-type transistor 318 is turned off. As a result, the second capacitor 320 is connected in parallel to the first capacitor 316, and a portion of the charges stored in the first capacitor 320 migrate to the second capacitor 320. From another perspective, the total capacitance increases due to the parallel connection, the voltage level at the output node A decreases as the total amount of charges stay unchanged.

When the clock signal (labeled as “CK” in FIG. 3B) is at logical low, the second n-type transistor 318 is turned off. In the meantime, the complementary clock signal (labeled as “CKB” in FIG. 3B) is accordingly at logical high, the third n-type transistor 318 is turned on. As a result, the second capacitor 320 is no longer connected in parallel to the first capacitor 316, and both sides of the second capacitor 320 is connected to the lower power rail (e.g., V_{SS} or ground). Therefore, the charges that migrate to the second capacitor 320 are released because the voltage drop becomes zero.

In the example shown in FIG. 3B, the current sensor 350 includes, among other components, another operational amplifier (may also be referred to as the “second operational amplifier”) 352, a sense transistor 395, a first p-type transistor 354, a second p-type transistor 356, and a third p-type transistor 358. The negative terminal of the operational amplifier 352 is coupled to the output node A of the peak detector 310, and the positive terminal of the operational amplifier 352 is coupled to the node C. The output terminal of the operational amplifier 352 is coupled to the gate of the first p-type transistor 354. The drain of the sense transistor 395 is coupled to the node C, and the source of the sense transistor 395 is coupled to the lower power rail (e.g., V_{SS} or ground). The gate of the sense transistor 395 is connected to the gate of the n-type output transistor 392.

Since the positive input terminal and the negative input terminal of the operational amplifier 352 are virtual short, the voltage level at the positive input terminal (and, therefore, the voltage level at the node C) is the same as the voltage level at the output node A of the peak detector 310. In other words, the voltage level at the output node A of the peak detector 310 is duplicated at the node C. As a result, the V_{DS} of the sense transistor 395 is the same as the peak value of the V_{DS} of the n-type output transistor 392. As discussed above with reference to FIG. 2D, the drain current of the sense transistor 395 is proportional to the drain current of the n-type output transistor 392 because the V_{DS} of the sense transistor 395 is clamped to the peak value of the V_{DS} of the n-type output transistor 392. In the example shown in FIG. 3B, the W/L ratio of the n-type output transistor 392 is M times of the W/L ratio of the sense transistor 395. As a result, the drain current of the sense transistor 395 is 1/M of the drain current of the n-type output transistor 392.

The source of the first p-type transistor 354 is coupled to the drain and the gate of the second p-type transistor 356, the drain of the first p-type transistor 354 is coupled to the node C. The voltage level at the output terminal is at low, and the first p-type transistor 354 is turned on, coupling the sense transistor 395 to the current mirror 360 comprised of the second p-type transistor 356 and the third p-type transistor 358. The source of the second p-type transistor 356 and the source of the third p-type transistor 358 are coupled to the higher power rail (e.g., V_{DD}). The drain of the second p-type transistor 356 is coupled to the gates of the second p-type transistor 356 and the third p-type transistor 358. In the example shown in FIG. 3B, the drain current of the third p-type transistor 358 is 1/N of the drain current of the second p-type transistor 356. As a result, the sense current (Isense) can be calculated in accordance with Isense=I_out_peak/(M*N), whereas I_out_peak is the peak value of the output current I_out flowing thorough the n-type output transistor 392. In one example, M is equal to 10. In another example, M is equal to 100. In yet another example, M is equal to 1000. In yet another example, M is equal to 10000. In one example, N is equal to 10. In another example, N is equal to 100. In yet another example, N is equal to 1000. It should be understood that these examples are not intended to be limiting, and other values may be employed in other embodiments.

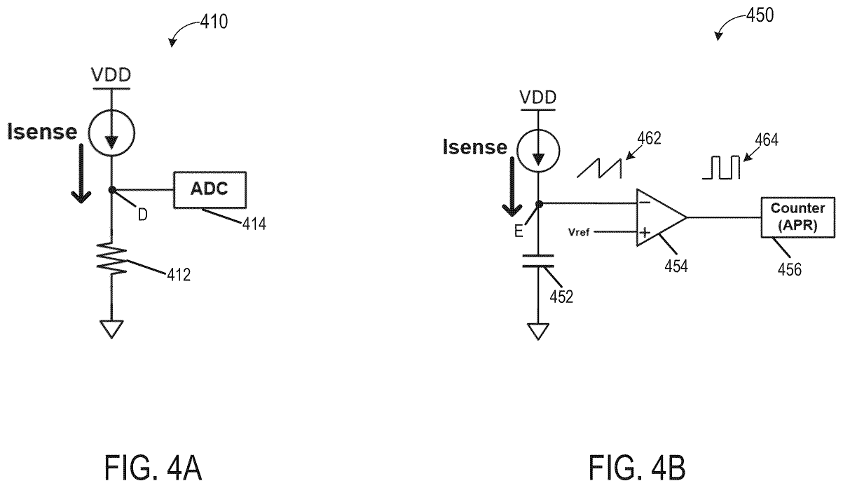

In some embodiments, the sense current (Isense) can be further converted to a digital signal for additional processing such as digital signal processing (DSP). FIG. 4A is a diagram illustrating an example conversion circuit 410 in accordance with some embodiments. FIG. 4B is a diagram illustrating another example conversion circuit 450 in accordance with some embodiments.

In the example shown in FIG. 4A, the conversion circuit 410 includes, among other components, a resistor 412 and an analog-to-digital converter (ADC) 414. The sense current (Isense) is represented by a current source connected between the higher power rail (e.g., V_{DD}) and a node D. The resistor 412 is connected between the node D and a lower power rail (e.g., V_{SS} or ground). The voltage level at the node D is calculated in accordance with Vsense=Isense*R, whereas R is the resistance of the resistor 412. The voltage level at the node D is input to the ADC 414, and the ADC 414 converts it into a digital value. However, the ADC 414 consumes a relatively large chip area and is typically associated with a relatively high cost.

In the example shown in FIG. 4B, the conversion circuit 450 includes, among other components, a capacitor 452, a comparator 454, and a counter 456. The sense current (Isense) is represented by a current source connected between the higher power rail (e.g., V_{DD}) and a node E. The capacitor 452 is connected between the node E and a lower power rail (e.g., V_{SS} or ground). The negative input terminal of the comparator 454 is coupled to the node E, and a reference voltage is supplied to the positive input terminal of the comparator 454. The output terminal of the comparator 454 is coupled to an input terminal of the counter 456.

As shown in FIG. 4B, the sense current charges the capacitor 452, and the charges stored by the capacitor 452 can be calculated in accordance with Q=C*V=Isense*Δt, whereas C is the capacitance of the capacitor 452, V is the voltage drop across the capacitor 452, and Δt is the charging period. As a result, Isense can be calculated in accordance with Isense=(C*V)/Δt.

The voltage drop (V) has a ramp signal waveform (labeled as “462” in FIG. 4B). The voltage drop (V) is compared to the reference voltage (labeled as “Vref” in FIG. 4B), and the resultant output signal of the comparator 454 has a PWM waveform (labeled as “462” in FIG. 4B). The pulse width of the PWM waveform corresponds to the charging period (Δt). The counter 456 receives a high-frequency clock signal as the input, and the counter the number of cycles of the counter clock signal for each pulse width of the PWM waveform. As such, the charging period (Δt) is counted, and the sense current Isense can be calculated in accordance with Isense=(C*V)/Δt, as explained above. The calculated sense current Isense is therefore digitalized.

It has been observed by the inventor that the absolute value of the error ratio of the current sensing circuit 300 shown in FIGS. 3A and 3B is between 0.4% and 1.3% at different output resistance (R1 shown in FIG. 3B) values. Specifically, when the output resistance is 4 ohm, the error ration is 0.4%; when the output resistance is 5 ohm, the error ration is −0.9%; when the output resistance is 6 ohm, the error ration is −1.3%; when the output resistance is 7 ohm, the error ration is −1.1%; when the output resistance is 8 ohm, the error ration is −1%.

Thus, this error ratio is significantly better that the absolute value of the error ration of the current sensing circuit shown in FIG. 2D, which is typically 10%. This advantage is achieved by capturing the peak value of the first output signal OUTM utilizing the peak detector 310, as explained above.

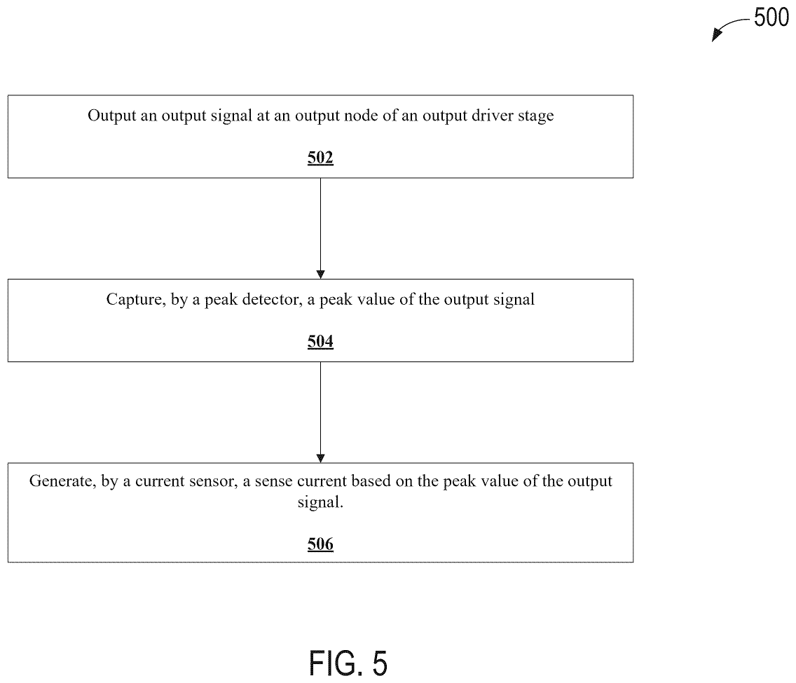

FIG. 5 is a flowchart diagram illustrating an example method for operating a class-D amplifier in accordance with some embodiments. In the example shown in FIG. 5, the method 500 includes operations (or steps) 502, 504, and 506. Additional operations may be performed.

At step 502, an output signal (e.g., the first output signal OUTM shown in FIG. 3B) is output, by an output driver stage (e.g., the output driver stage 390 shown in FIG. 3B) of a class-D amplifier, at an output node of the output driver stage.

At step 504, a peak value of the output signal is captured by a peak detector (e.g., the peak detector 310 shown in FIG. 3B).

At step 506, a sense current is generated, by a current sensor (e.g., the current sensor 350 shown in FIG. 3B), based on the peak value of the output signal.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A class-D amplifier, comprising:
an output driver stage configured to output an output signal at an output node;
a current sensing circuit coupled to the output node of the output driver stage and comprising:
a peak detector coupled to the output node of the output driver stage configured to capture a peak value of the output signal; and
a current sensor coupled to the peak detector and configured to receive the peak value of the output signal and generate a sense current based on the peak value of the output signal.

2. The class-D amplifier of claim 1, wherein the peak detector locks in the peak value of the output signal.

3. The class-D amplifier of claim 1, wherein the peak detector comprises an output node of the peak detector, and wherein when the output signal at the output node of the output driver stage increases, a voltage level at the output node of the peak detector increases, when the output signal at the output node of the output driver stage decreases, the voltage level at the output node of the peak detector remains unchanged.

4. The class-D amplifier of claim 1, wherein the peak detector comprises:
a first operational amplifier;
a first n-type transistor; and
a first capacitor.

5. The class-D amplifier of claim 4, wherein a positive input terminal of the first operational amplifier is coupled to output node of the output driver stage, a negative input terminal of the first operational amplifier is coupled to an output node of the peak detector, and an output terminal of the first operational amplifier is coupled to a gate of the first n-type transistor.

6. The class-D amplifier of claim 5, wherein a drain of the first n-type transistor is coupled to a higher power rail, and a source of the first n-type transistor is coupled to an output node of the peak detector.

7. The class-D amplifier of claim 6, wherein the first capacitor is coupled between the output node of the peak detector and a lower power rail lower than the higher power rail.

8. The class-D amplifier of claim 7, wherein the peak detector further comprises:
a second n-type transistor;
a third n-type transistor; and
a second capacitor.

9. The class-D amplifier of claim 8, wherein a drain of the second n-type transistor is coupled to the output node of the peak detector, a source of the second n-type transistor is coupled a second node, and wherein the second capacitor is coupled between the second node and the lower power rail, and wherein a drain of the third n-type transistor is coupled to the second node, and a source of the third n-type transistor is coupled to the lower power rail.

10. The class-D amplifier of claim 9, wherein a gate of the second n-type transistor is coupled to a first clock signal, and a gate of the third n-type transistor is coupled to a second clock signal, and the second clock signal is complementary to the first clock signal.

11. The class-D amplifier of claim 10, wherein a capacitance of the second capacitor is smaller than a capacitance of the first capacitor.

12. The class-D amplifier of claim 1, wherein the current sensor comprises:
a second operational amplifier;
a sense transistor;
a first p-type transistor; and
a current mirror.

13. The class-D amplifier of claim 12, wherein a negative input terminal of the second operational amplifier is coupled to the peak detector to receive the peak value of the output signal of the output driver stage, a positive input terminal of the second operational amplifier is coupled to a third node, and an output terminal of the second operational amplifier is coupled to a gate of the first p-type transistor, and wherein a source of the first p-type transistor is coupled to the current mirror, and a drain of the first p-type transistor is coupled to the third node.

14. The class-D amplifier of claim 13, wherein a drain of the sense transistor is coupled to the third node, and a source of the sense transistor is coupled to a lower power rail.

15. The class-D amplifier of claim 14, wherein the current mirror comprises:
a second p-type transistor, wherein the source of the first p-type transistor is coupled to a drain and a gate of the second p-type transistor, and a source of the second p-type transistor is coupled to a higher power rail higher than the lower power rail; and
a third p-type transistor, wherein a source of the third p-type transistor is coupled to the higher power rail, a gate of the third p-type transistor is coupled to the gate of the second p-type transistor, and a drain of the third p-type transistor is coupled to an output terminal of the current sensor.

16. The class-D amplifier of claim 15, wherein the output terminal of the current sensor is coupled to a conversion circuit comprising:
a capacitor coupled between the output terminal of the current sensor and the lower power rail;
a comparator comprising a negative input terminal coupled to the output terminal of the current sensor and a positive input terminal configured to receive a reference voltage; and
a counter coupled to an output terminal of the comparator.

17. A method for operating a class-D amplifier, the method comprising:
outputting an output signal at an output node of an output driver stage;
capturing, by a peak detector, a peak value of the output signal; and
generating, by a current sensor, a sense current based on the peak value of the output signal.

18. The method of claim 17, wherein capturing the peak value of the output signal further comprises:
locking in the peak value of the output signal.

19. The method of claim 18, wherein when the output signal increases, a voltage level at the output node of the peak detector increases, and when the output signal decreases, the voltage level at the output node of the peak detector remains unchanged.

20. The method of claim 17, further comprising:
converting the sense current to a digital sense current using a comparator and a counter.
